(19) United States
(12) Patent Application Publication
(10) Pub. No.: US 2021/0125830 A1
(43) Pub. Date: Apr. 29, 2021

(54) METHOD OF FORMING AN ASHABLE HARD MASK AND PATTERNING METHOD

(71) Applicant: NANYA TECHNOLOGY CORPORATION, New Taipei City (TW)

(72) Inventor: Wei-Chuan FANG, New Taipei City (TW)

(21) Appl. No.: 16/662,011

(22) Filed: Oct. 23, 2019

(51) Int. Cl. H01L 21/033; H01L 21/311

(52) U.S. Cl. CPC H01L 21/0337; H01L 21/31144

(57) ABSTRACT

Disclosed is a method of forming an ashable hard mask and a patterning method. The method of forming the ashable hard mask includes (i) providing a target layer; (ii) depositing an initial hard mask layer on the target layer; (iii) implanting the initial hard mask layer with carbon atoms under an implantation temperature of 400 to 700° C. to form an ashable hard mask, in which an implant dosage concentration in the ashable hard mask ranges from 10¹⁴ to 10¹⁶ ion/cm².

### BACKGROUND

### Field of Invention

The present invention relates to a method of forming an ashable hard mask and a patterning method.

### Description of Related Art

Hard mask is commonly used in the manufacturing process of semiconductor devices. The pattern wiggling phenomenon of the patterned features in semiconductor devices is undesired, especially as the feature size of semiconductor devices shrinks to sub-100 nm scale. In order to obtain good line patterns, the issue of wiggling phenomenon needs to be resolved.

### SUMMARY

The invention provides a method of forming an ashable hard mask, comprising (i) providing a target layer; (ii) depositing an initial hard mask layer on the target layer; (iii) implanting the initial hard mask layer with carbon atoms under an implantation temperature of 400 to 700° C. to form an ashable hard mask, in which an implant dosage concentration in the ashable hard mask ranges from 10¹⁴ to 10¹⁶ ion/cm².

In one embodiment of the present disclosure, before step (ii), further comprising scrubbing the target layer.

In one embodiment of the present disclosure, after step (ii) and before step (iii), further comprising performing a bevel etching on the initial hard mask layer.

In one embodiment of the present disclosure, step (iii) is performed under an implant dosage energy ranging from 10 to 50 keV.

In one embodiment of the present disclosure, the implantation temperature ranges from 500 to 600° C.

In one embodiment of the present disclosure, step (ii) includes exposing the target layer to a precursor gas comprising a CₓH_{y}-based gas.

In one embodiment of the present disclosure, the precursor gas comprises C₃H₆.

In one embodiment of the present disclosure, the initial hard mask layer comprises a carbon-based material.

In one embodiment of the present disclosure, the target layer comprises nitride or oxide.

The present disclosure also provides a patterning method. The patterning method comprises (i) forming a target layer on a substrate; (ii) forming an initial hard mask layer on the target layer; (iii) implanting the initial hard mask layer with carbon atoms under an implantation temperature of 400 to 700° C. to form an ashable hard mask, in which an implant dosage concentration in the ashable hard mask ranges from 10¹⁴ to 10¹⁶ ion/cm²; (iv) patterning the ashable hard mask to form a patterned ashable hard mask exposing a portion of the target layer; (v) etching the exposed portion of the target layer by using the patterned ashable hard mask as a mask; and (vi) ashing the patterned ashable hard mask.

In one embodiment of the present disclosure, step (i) comprises scrubbing the target layer before forming the initial hard mask layer.

In one embodiment of the present disclosure, after step (ii) and before step (iii), further comprising performing a bevel etching on the initial hard mask layer.

In one embodiment of the present disclosure, step (iii) is performed under an implant dosage energy ranging from 10 to 50 keV.

In one embodiment of the present disclosure, the implantation temperature ranges from 500 to 600° C.

In one embodiment of the present disclosure, the initial hard mask layer comprises a carbon-based material.

In one embodiment of the present disclosure, the target layer comprises nitride or oxide.

It is to be understood that both the foregoing general description and the following detailed description are by examples, and are intended to provide further explanation of the invention as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a patterning method according to some embodiments of the disclosure.

FIG. 2 to FIG. 10 illustrate a series of cross-sectional views of various intermediary stages of the patterning method according to some embodiments of the disclosure.

### DETAILED DESCRIPTION

In order to make the description of the present disclosure more detailed and complete, the following illustratively describes implementation aspects and specific embodiments of the present disclosure; however, this is not the only form in which the specific embodiments of the present disclosure are implemented or utilized. The embodiments disclosed below may be combined with or substituted by each other in an advantageous manner, and other embodiments may be added to an embodiment without further recording or description. In the following description, numerous specific details will be described in detail to enable readers to fully understand the following embodiments. However, the embodiments of the present disclosure may be practiced without these specific details.

Although below using a series of actions or steps described in this method disclosed, but the order of these actions or steps shown should not be construed to limit the present invention. For example, certain actions or steps may be performed in different orders and/or concurrently with other steps. Moreover, not all steps must be performed in order to achieve the depicted embodiment of the present invention. Furthermore, each operation or procedure described herein may contain several sub-steps or actions.

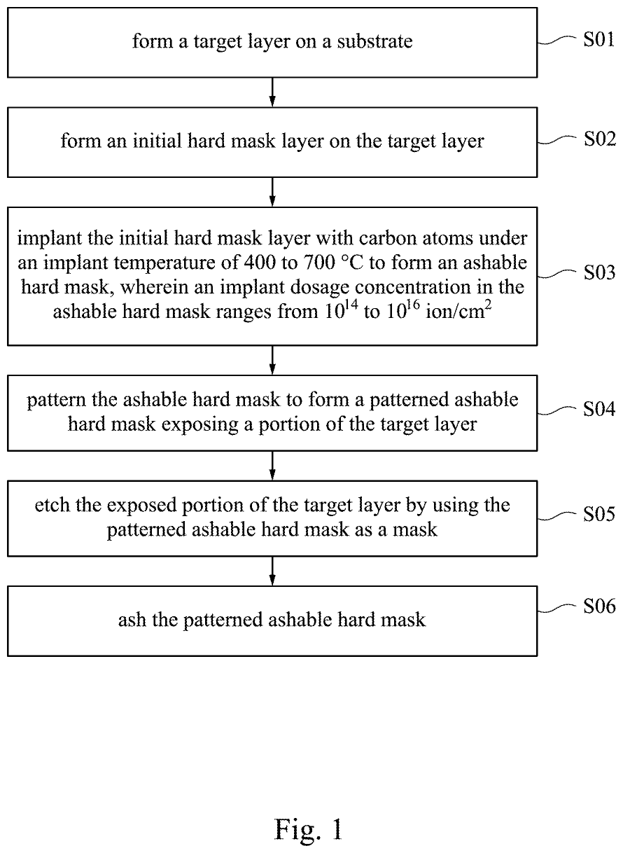

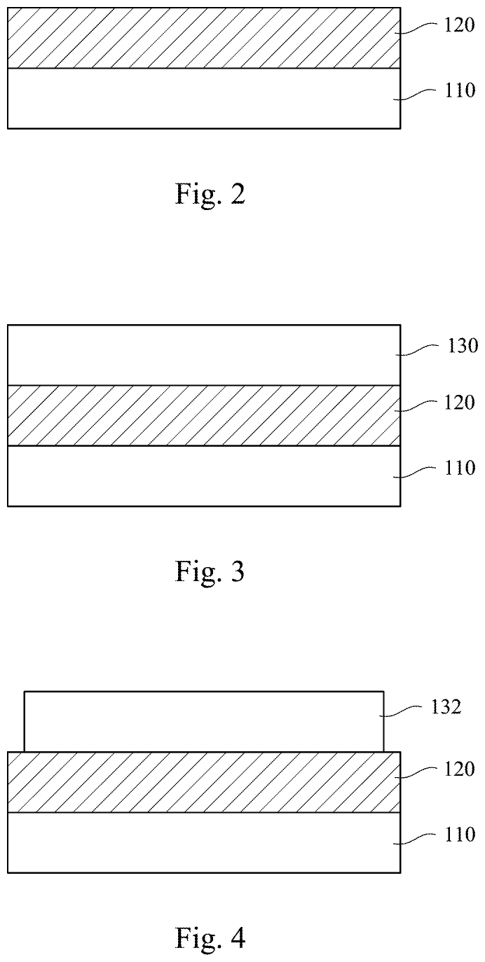

FIG. 1 is a flow chart illustrating a patterning method according to some embodiments of the disclosure. As shown in FIG. 1, method 10 includes step S01 to step S06. FIG. 2 to FIG. 10 illustrate a series of cross-sectional views of various intermediary stages of the patterning method according to some embodiments of the disclosure.

Reference is made to FIG. 1 and FIG. 2. At step S01, a substrate 110 and a target layer 120 formed thereon are provided, as shown in FIG. 2. In some embodiments, the target layer 120 may include nitride or oxide, such as silicon oxide, silicon nitride, and titanium nitride. In other embodiments, the target layer 120 may include polysilicon or metal such as copper, tungsten and aluminum.

At step S02, an initial hard mask layer 130 is formed on the target layer 120, as shown in FIG. 3. In some embodiments of the present disclosure, before forming the initial hard mask layer 130 on the target layer 120, the target layer 120 is scrubbed to remove particles on the surface. In one embodiment, a queue-time (Q-time) before the formation of the initial hard mask layer 130 may range from 0 to 24 hours, preferably 0 to 12 hours, such as 2, 4, or 6 hours. If the Q-time is greater than 24 hours, defects may be found on the surface of the target layer 120.

In one embodiment of the present disclosure, the initial hard mask layer 130 is deposited on the target layer 120 by a plasma-enhanced chemical vapor deposition process. Specifically, the target layer 120 is exposed to a precursor gas comprising a CₓH_{y}-based gas, in which x is an integer of 2-6, y is an integer of 2-14, such as C₂H₂, C₃H₆, C₄H₁₀, C₆H₆, or a combination thereof. In one embodiment, the precursor gas is diluted by a bulk gas such as N₂, He, Ar, or a combination thereof. In one embodiment, the initial hard mask layer 130 comprises a carbon-based material, such as amorphous carbon.

In one embodiment of the present disclosure, after step S02, a bevel etching is optionally performed on the initial hard mask layer 130 to form an etched initial hard mask layer 132, as shown in FIG. 4.

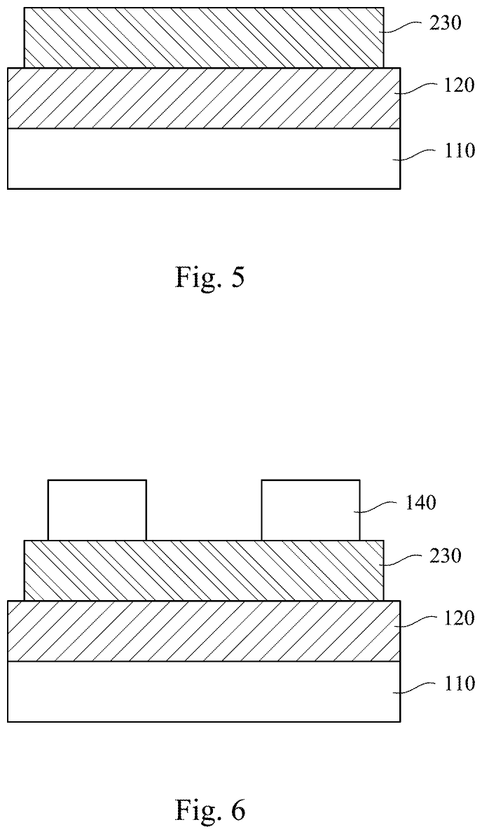

Reference is now made to FIG. 5. At step S03, the initial hard mask layer 130 or the etched initial hard mask layer 132 is implanted with carbon atoms under an implantation temperature of 400 to 700° C. to form an ashable hard mask 230. In some embodiments, the implantation temperature may range from 450 to 650° C., preferably 500 to 600° C., such as 530° C., 550° C. or 580° C. If the implantation temperature is smaller than 400° C., the degree of crystallinity of the ashable hard mask 230 after implantation is low, thereby affecting the film quality and resulting in high compressive stress. If the implantation temperature is greater than 700° C., excessive sp³ bond formation may occur in the ashable hard mask 230 after implantation, which will also increase the compressive stress, and some impurities such as oxygen may be found in the ashable hard mask 230.

In one embodiment of the present disclosure, step S03 is performed under an implant dosage energy ranging from 10 to 50 keV, preferably 20 to 45 keV, more preferably 30 to 40 keV. If the implant dosage energy is smaller than 10 keV, the penetration depth of the dopants may be insufficient. If the implant dosage energy is greater than to 50 keV, the ashable hard mask 230 may be damaged during the implantation process.

In some embodiments, an implant dosage concentration in the ashable hard mask 230 ranges from 10¹⁴ to 10¹⁶ ion/cm², such as 5×10¹⁴ ion/cm², 1×10¹⁵ ion/cm², or 5×10¹⁵ ion/cm². It is observed that when the implant dosage concentration is smaller than 10¹⁴ ion/cm², there is an insufficient amount of sp³ bond formation in the ashable hard mask 230, such that some mechanical properties (such as modulus) of the ashable hard mask 230 may not be satisfactory. On the other hand, if the implant dosage concentration is greater than 10¹⁶ ion/cm², there is an excessive amount of sp³ bond formation in the ashable hard mask 230, which may increase the compression stress.

In some embodiments, an implantation incidence angle (i.e., an angle between the impinging dopants and the ashable hard mask 230 may range from 45° to 90°, preferably 50° to 85°, more preferably 60° to 80°. If the implantation incidence angle is smaller than 45°, the dopants cannot penetrate to sufficient depth. If the implantation incidence angle is greater than 90°, the implant dosage concentration may be low.

It is appreciated that the ashable hard mask 230 provided from steps S01 through S03 has low compression stress. Therefore, during the subsequent etching of the target layer 120, the patterned target layer is not prone to pattern wiggling phenomenon. In some embodiments, the compression stress of the ashable hard mask formed by the present method may near to zero. In some embodiments, the compression stress of the ashable hard mask formed by the present method may range from 0-300 MPa. It is noted that in the conventional ashable hard mask, the compression stress may range from 500 MPa to 1 GPa, which may aggravate the pattern wiggling phenomenon.

The present disclosure also provides a patterning method. Reference is now invited to step S04 in continuance of steps S01 to S03. At step S04, the ashable hard mask is patterned to form a patterned ashable hard mask exposing a portion of the target layer. FIG. 6 to FIG. 8 illustrates the detailed process of implementing step S04. Referring to FIG. 6, a photoresist 140 with a pattern is disposed on the ashable hard mask 230. The photoresist 140 may be a polymeric material. In some embodiments, the pattern of the photoresist 140 may be formed by a photolithography process using a radiation source of mercury vapor lamp, xenon lamp, carbon arc lamp, a KrF excimer laser light, an ArF excimer laser light, or an F₂ excimer laser light.

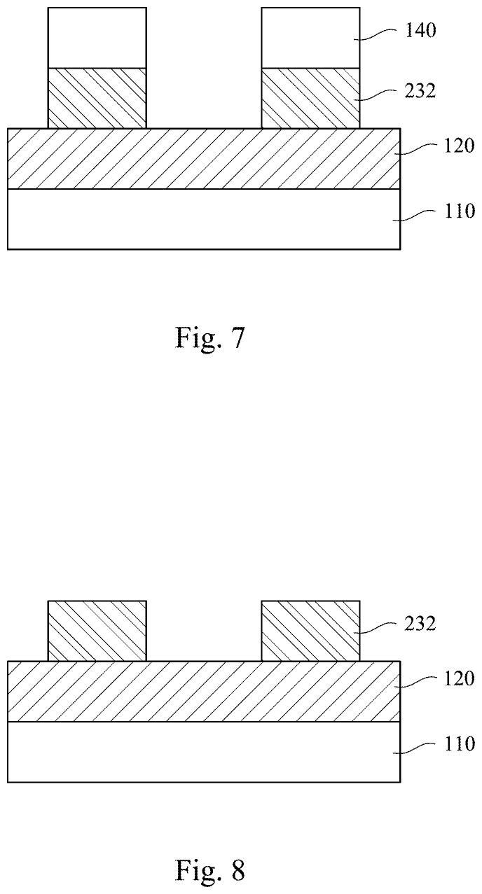

Next, referring to FIG. 7, the ashable hard mask 230 is etched, such that the pattern of the photoresist 140 is transferred to the ashable hard mask 230, thereby forming a patterned ashable hard mask 232. A portion of the target layer 120 is exposed from the patterned ashable hard mask 232. In some embodiments, the ashable hard mask 230 is etched by, for example, a plasma etching process. Then, referring to FIG. 8, the photoresist 140 is removed.

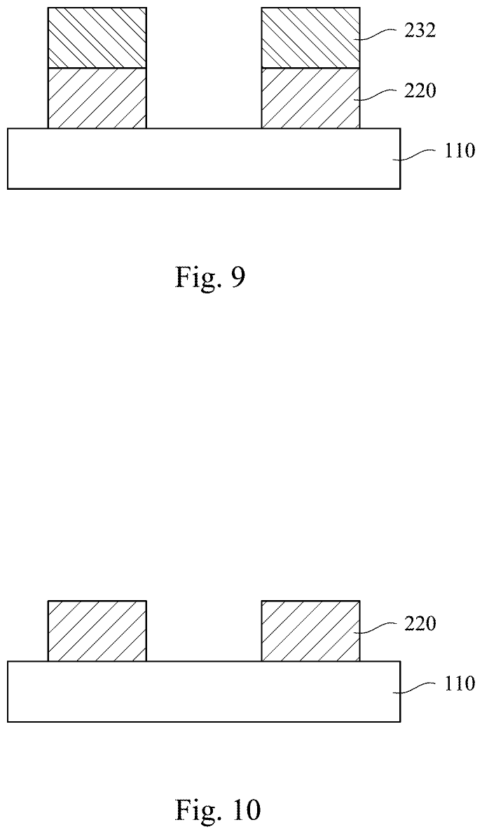

At step S05, the exposed portion of the target layer is etched by using the patterned ashable hard mask as a mask. As illustrated in FIG. 9, the exposed portion of the target layer 120 is etched by using the patterned ashable hard mask 232 as a mask, such that a patterned target layer 220 is formed. In one embodiment, the exposed portion of the target layer 120 is etched by exposing the target layer 120 to a halogen-containing etchant, such as Cl₂, BCl₃, CF₃, CHF₃, and the like. A portion of the substrate 110 is exposed from the patterned target layer 220.

At step S06, the patterned ashable hard mask is ashed. As illustrated in FIG. 10, the patterned ashable hard mask 232 is ashed, and the patterned target layer 220 is remained on the substrate 110. In one embodiment, oxygen radicals in plasma form are used to oxidize the patterned ashable hard mask 232, such that the patterned ashable hard mask 232 is ashed.

In summary, the method of the present disclosure can efficiently prevent the pattern wiggling phenomenon of the patterned target layer 220. Specifically, the patterned ashable hard mask 232 of the present disclosure has low compression stress, such that the patterned target layer 220 is not prone to pattern wiggling phenomenon by using the patterned ashable hard mask 232 as a mask during etching. Moreover, the patterned ashable hard mask 232 can be easily removed by an ashing technique.

Further, additional annealing and continuous lithography, etching, or implantation processes are not required in the method of the present disclosure. That is, the present method provides a straightforward approach to form a patterned feature that is not prone to pattern wiggling phenomenon.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of forming an ashable hard mask, comprising:
(i) providing a target layer;
(ii) depositing an initial hard mask layer on the target layer; and
(iii) implanting the initial hard mask layer with carbon atoms under an implantation temperature of 400 to 700° C. to form an ashable hard mask, wherein an implant dosage concentration in the ashable hard mask ranges from 10¹⁴ to 10¹⁶ ion/cm².

2. The method of claim 1, before step (ii), further comprising scrubbing the target layer.

3. The method of claim 1, after step (ii) and before step (iii), further comprising performing a bevel etching on the initial hard mask layer.

4. The method of claim 1, wherein step (iii) is performed under an implant dosage energy ranging from 10 to 50 keV.

5. The method of claim 1, wherein the implantation temperature ranges from 500 to 600° C.

6. The method of claim 1, wherein step (ii) includes exposing the target layer to a precursor gas comprising a CₓH_{y}-based gas.

7. The method of claim 6, wherein the precursor gas comprises C₃H₆.

8. The method of claim 1, wherein the initial hard mask layer comprises a carbon-based material.

9. The method of claim 1, wherein the target layer comprises nitride or oxide.

10. A patterning method, comprising:
(i) forming a target layer on a substrate;
(ii) forming an initial hard mask layer on the target layer;
(iii) implanting the initial hard mask layer with carbon atoms under an implantation temperature of 400 to 700° C. to form an ashable hard mask, wherein an implant dosage concentration in the ashable hard mask ranges from 10¹⁴ to 10¹⁶ ion/cm²;
(iv) patterning the ashable hard mask to form a patterned ashable hard mask exposing a portion of the target layer;
(v) etching the exposed portion of the target layer by using the patterned ashable hard mask as a mask; and
(vi) ashing the patterned ashable hard mask.

11. The method of claim 10, wherein step (i) comprises scrubbing the target layer before forming the initial hard mask layer.

12. The method of claim 10, after step (ii) and before step (iii), further comprising performing a bevel etching on the initial hard mask layer.

13. The method of claim 10, wherein step (iii) is performed under an implant dosage energy ranging from 10 to 50 keV.

14. The method of claim 10, wherein the implantation temperature ranges from 500 to 600° C.

15. The method of claim 10, wherein the initial hard mask layer comprises a carbon-based material.

16. The method of claim 10, wherein the target layer comprises nitride or oxide.
